(19) United States
(12) Patent Application Publication
(10) Pub. No.: US 2006/0172480 A1
(43) Pub. Date: Aug. 3, 2006

(54) Single metal gate CMOS device design

(75) Inventors: Chih-Hao Wang, Hsin-Chu (TW); Shang-Chih Chen, Hsin-Chu (TW); Ching-Wei Tsai, Hsin-Chu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Taiwan Semiconductor Manufacturing Company, Ltd.

(21) Appl. No.: 11/048,877

(22) Filed: Feb. 3, 2005

(51) Int. Cl. H01L 21/8238; H01L 21/3205; H01L 21/8234

(52) U.S. Cl. 438/199; 438/585; 438/197

(57) ABSTRACT

A semiconductor device includes a PMOS transistor formed on a substrate structure. The PMOS transistor includes a source and a drain each including a diffusion region in the substrate structure, a channel region defined between the source and the drain, a gate dielectric over the channel region, and a gate electrode over the gate dielectric. The gate electrode is formed of a material having an n-type work function with respect to the semiconductor substrate and is treated such that a work function of the gate electrode is converted into a mid-gap type or p-type work function with respect to the semiconductor substrate.

### TECHNICAL FIELD

This invention relates generally to a semiconductor device and, more particularly, to a p-type MOS transistor having a gate comprising the same metal as a gate of an NMOS transistor, a single metal gate CMOS device, and methods for making the same.

### BACKGROUND

Complementary metal-oxide-semiconductor (CMOS) devices have been widely used in electronic circuits where low power consumption is desired. This is because, in a CMOS device including a pair of p-type MOS (PMOS) transistor and n-type MOS (NMOS) transistor, generally only one of the PMOS and NMOS transistors is turned on to conduct current. To obtain satisfactory performance, such as a full swing of output range between power supply voltages, the PMOS and NMOS transistors in a CMOS device should have threshold voltages substantially close to each other. For example, in some small scale integrated circuits (IC's), it is required that the PMOS transistor have a threshold voltage of −0.2V˜−0.4V, and that the NMOS transistor have a threshold voltage of 0.2V˜0.4V.

A conventional MOS transistor 100 is illustrated in FIG. 1A. MOS transistor 100 is formed on a silicon substrate 102, and includes a source 104 and a drain 106 each formed as a diffusion region in substrate 102. A channel region 108 is defined between source 104 and drain 106. MOS transistor 100 also includes a layer of gate dielectric 110 and a gate electrode or gate 112 formed sequentially over channel region 108. Gate dielectric 110 may comprise an insulating material such as silicon oxide or a metal oxide. Gate 112 may comprise a conductive material such as doped polysilicon or a metal.

The threshold voltage of MOS transistor 100 depends on a number of factors including the doping concentration of substrate 102, the band structure of substrate 102, the properties of gate dielectric 110, and the properties of gate 112. FIGS. 1B-1D, which illustrate band diagrams of MOS transistor 100 along line A-A′ of FIG. 1A, are referred to for an explanation of such determinants of the threshold voltage.

FIG. 1B illustrates the energy levels of gate 112, gate dielectric 110, and substrate 102 when they are separated from one another, and may be referred to as a flat band diagram. It is assumed that substrate 102 is doped with n-type impurities and MOS transistor 100 is a PMOS transistor. In FIG. 1B, E_{Gate} and E_{F} are the respective Fermi levels of gate 112 and substrate 102, the Fermi level being defined as the energy level at which the probability of occupation of electron states is ½. A work function of a material is defined as the energy needed to remove an electron from an atom of the material at the Fermi level to vacuum, i.e., to outside of the atom. Thus, as shown in FIG. 1B, qΦ_{Gate} is the work function of gate 112, and qΦ_{S} is the work function of substrate 102, where q is the charge of an electron. FIG. 1B also shows the conduction band E_{CK}, the valence band E_{VK}, and the electron affinity qΦᵢ of gate dielectric 110, wherein the electron affinity is defined as the energy between the vacuum level and the bottom of the conduction band. FIG. 1B further shows the conduction band E_{C}, the valence band E_{V}, and the mid-gap level Eᵢ of substrate 102. qΨ_{B} is the difference between the Fermi level E_{F} and the mid-gap level Eᵢ of substrate 102, and qΦ_{iS} is an electron energy barrier between gate dielectric 110 and substrate 102.

When gate 112, gate dielectric 110, and substrate 102 are brought together to form an MOS structure, various carrier transport mechanisms exist in the MOS structure such that electrons and/or holes by nature move from higher energy levels to lower energy levels. For example, if the Fermi level of substrate 102 is higher than the Fermi level of gate 112, i.e., substrate 102 has more electrons at higher energy levels than gate 112, electrons move from substrate 102 to gate 112 by either tunneling through gate dielectric 110 (when gate dielectric 110 is very thin) and/or overcoming energy barrier qΦ_{iS} between gate dielectric 110 and substrate 102, until an equilibrium state is reached. Therefore, if no bias is applied to gate 112 or substrate 102, at the equilibrium state, the Fermi levels of gate 112 and substrate 102 should be equal to each other. FIG. 1C illustrates a band diagram of PMOS transistor 100 along line A-A′ of FIG. 1A, when no bias is applied to gate 112 or substrate 102. As shown in FIG. 1C, at the equilibrium state, the Fermi level of gate 112, E_{Gate}, shifts upward with respect to the energy levels of the bulk of substrate 102 by an amount of qΦ_{GS}, where Φ_{GS}=Φ_{Gate}−Φ_{S}. To maintain the continuity of the vacuum level, the energy band of substrate 102 bends upward at the interface between substrate 102 and gate dielectric 110 and the energy levels of gate dielectric 110 also bends upward towards the interface between gate dielectric 110 and gate 112.

When a negative bias is applied to gate 112 with respect to substrate 102, the Fermi level of gate 112 shifts further upward and the energy band of substrate 102 bends further upward at the interface between substrate 102 and gate dielectric 110, as shown in FIG. 1D. Conventionally, a strong inversion is said to occur at the interface between gate dielectric 110 and substrate 102, thus creating a channel in channel region 108, when the Fermi level EF is lower than the mid-gap level Eᵢ near the interface between gate dielectric 110 and substrate 102 by approximately the same amount by which the Fermi level E_{F} is greater than the mid-gap level Eᵢ in bulk substrate 102, i.e., qΨ_{B} PMOS transistor 100 is considered turned on when the strong inversion occurs. Thus, assuming that the energy levels of gate dielectric 110 bends upward towards the interface between gate dielectric 110 and gate 112 by an amount qVᵢ, then the threshold voltage of PMOS transistor 100 is given by Formula (1):
|Vₜₕ|=2Ψ_{B}−Φ_{GS}+Vᵢ. (1)

Clearly, from Formula (1), to obtain a low threshold voltage of a PMOS transistor, it is desirable to use a material having a large work function Φ_{Gate}. Following the same rationale, it would be desirable to use a material having a small work function Φ_{Gate} in a gate of an NMOS transistor to achieve a small threshold voltage. Generally, to achieve a threshold voltage of 0.2 V˜0.4 V for an NMOS transistor formed on a silicon substrate, an appropriate gate material should have a work function of about 4 eV; and, to achieve a threshold voltage of −0.2 V˜−0.4 V for an PMOS transistor formed on a silicon substrate, an appropriate gate material should have a work function of about 5 eV.

Conventionally, a CMOS device uses either doped polysilicon or a metal as gates of the PMOS and NMOS transistors thereof. For example, a p⁺ polysilicon may be used as the gate of the PMOS transistor, while an n⁺ polysilicon may be used as the gate of the NMOS transistor. Alternatively, a CMOS device may use a dual metal gate structure; namely, a metal having a large work function may be used as the gate of the PMOS transistor of a CMOS device and a metal having a small work function may be used as the gate of the NMOS transistor.

CMOS devices using polysilicon doped with p⁺ and n⁺ impurities for the gates of the PMOS and NMOS transistors have certain advantages, such as high selectivity over gate dielectric, easy deposition, good compatibility with processing of other parts of the devices, and easy control of the work function. However, polysilicon gate electrodes have problems such as gate depletion effect, boron (a dopant in p⁺ polysilicon) penetration into the gate dielectric layer, and lower gate resistance. Also, when the CMOS devices are scaled down and the gate dielectric layer is very thin, remote phonon scattering resulting from carriers tunneling into the gate reduces carrier mobility in the channel region, thereby reducing the operation speed of the devices.

On the other hand, because two different metals need to be used, CMOS devices using dual metal gate structures require significantly more complex processing techniques.

### SUMMARY OF THE INVENTION

The present invention provides for a CMOS device in which a single metal is used to form the gates for both an NMOS transistor and a PMOS transistor and a method for manufacturing the same.

Consistent with the present invention, there is provided a semiconductor device includes a PMOS transistor formed on a substrate structure. The PMOS transistor includes a source and a drain each including a diffusion region in the substrate structure, a channel region defined between the source and the drain, a gate dielectric over the channel region, and a gate electrode over the gate dielectric. The gate electrode is formed of a material having an n-type work function with respect to the semiconductor substrate and is treated such that a work function of the gate electrode is converted into a mid-gap type or p-type work function with respect to the semiconductor substrate.

Consistent with the present invention, there is also provided a semiconductor device that includes an NMOS transistor formed in a first region of a semiconductor substrate and a PMOS transistor formed in a second region. The NMOS transistor includes a source and a drain each including a diffusion region, a channel region defined between the source and the drain, a gate dielectric over the channel region, and a gate electrode over the gate dielectric. The PMOS transistor includes a source and a drain each including a diffusion region, a channel region defined between the source and the drain, a gate dielectric over the channel region, and a gate electrode over the gate dielectric. The gate electrode of the NMOS transistor and the gate electrode of the PMOS transistor are formed of the same material having an n-type work function with respect to the semiconductor substrate and the gate electrode of the PMOS transistor is treated to convert the n-type work function to a mid-gap type or p-type work function with respect to the semiconductor substrate.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the objects, advantages, and principles of the invention.

In the drawings,

FIG. 1A shows a conventional MOS transistor;

FIGS. 1B-1D illustrate band diagrams of the conventional MOS transistor of FIG. 1A along line A-A′ in FIG. 1A;

FIG. 2A shows a PMOS transistor consistent with a first embodiment of the present invention;

FIGS. 2B-2D illustrate band diagrams of the PMOS transistor of FIG. 2A along line B-B′ in FIG. 2A;

FIG. 3 shows a PMOS transistor consistent with a second embodiment of the present invention;

FIG. 4 shows a CMOS device consistent with a third embodiment of the present invention; and

FIG. 5 shows a CMOS device consistent with a fourth embodiment of the present invention.

### DESCRIPTION OF THE EMBODIMENTS

Reference will now be made in detail to the preferred embodiments of the invention, examples of which are illustrated in the accompanying drawings. Wherever possible, the same reference numbers will be used throughout the drawings to refer to the same or like parts.

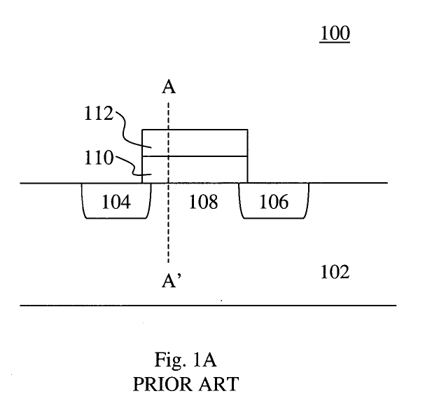

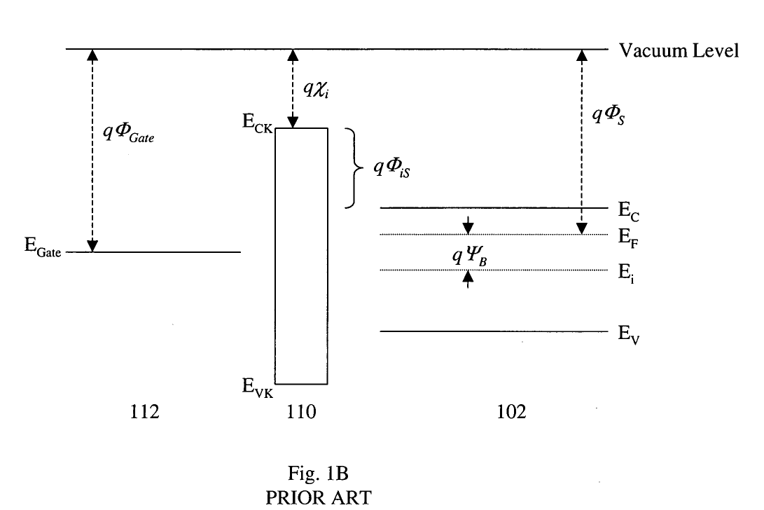

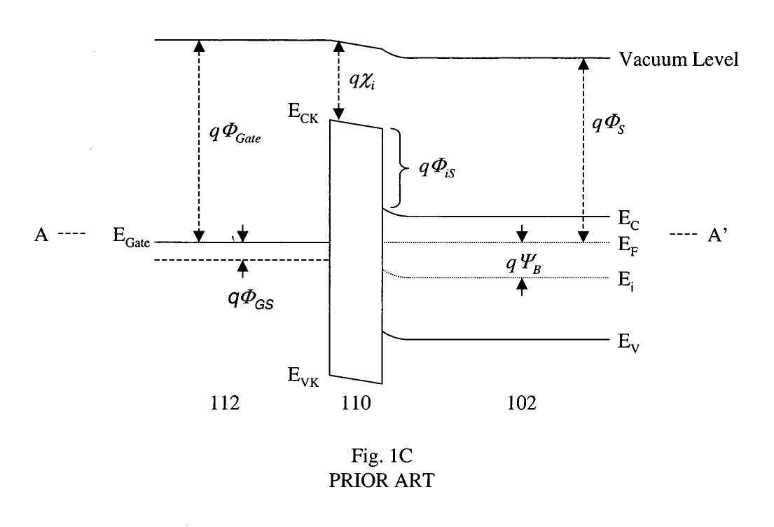

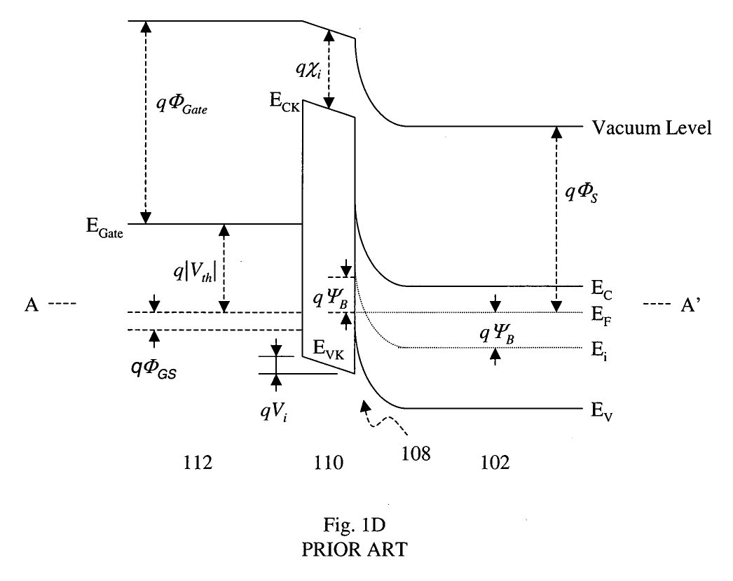

For convenience of description, in an MOS structure including a gate, a semiconductor substrate, and a gate dielectric therebetween, the type of the work function of the gate with respect to the semiconductor substrate is defined as the conductivity type of the semiconductor material constituting the semiconductor substrate of the MOS structure if the semiconductor material has the same Fermi level as the gate. For example, in a flat band diagram such as shown in FIG. 1B, if the Fermi level of the gate E_{Gate} is above the mid-gap level of the semiconductor substrate, Eᵢ, the work function of the gate is said to be of n type, and if the Fermi level of the gate is close to the conduction band of the semiconductor substrate, the work function of the gate is said to be of n⁺ type. Similarly, if the Fermi level of the gate is below the mid-gap level of the semiconductor substrate, the work function of the gate said be of p type. If the Fermi level of the gate is close to the mid-gap level of the semiconductor substrate, the gate is said to have a mid-gap work function. For example, in FIG. 1B, because the Fermi level E_{Gate} of gate 112 is above mid-gap level Eᵢ of substrate 100, gate 112 has an n-type work function. Accordingly, a p-type work function is larger than an n-type work function. Based on this definition of work function type, it is desirable to use a material having an n-type work function as a gate of an NMOS transistor and a material having a p-type work function as a gate of a PMOS transistor.

Consistent with the present invention, there is provided a CMOS device in which a single metal material is used to fabricate the gates for both an NMOS transistor and a PMOS transistor. Particularly, a metal having an n-type work function is used to fabricate the gates of both the NMOS transistor and the PMOS transistor. As a result, the complexity of the manufacturing process of the CMOS device is reduced as compared to conventional dual-metal-gate CMOS devices. Exemplary metals that have n-type work functions when used as the gate of an MOS transistor formed on a silicon substrate include titanium (Ti), tantalum (Ta), aluminum (Al), zirconium (Zr), niobium (Nb), etc. Exemplary metallic compounds that have n-type work functions when used as the gate of an MOS transistor formed on a silicon substrate include tantalum nitride (TaN), tantalum silicon nitride (TaSiₓN_{y}), ruthenium tantalum (Ru₁₋ₓTaₓ), etc. Such metals or metal compounds may be used as the gates of both the NMOS transistor and the PMOS transistor consistent with the present invention.

However, as Formula (1) shows, when a material having an n-type work function is used as a gate of a PMOS transistor, the PMOS transistor has a large threshold voltage because Φ_{GS} is small. The present invention accordingly provides for improvements of a PMOS transistor using a material having an n-type work function such that the threshold voltage of the PMOS transistor is lowered to an appropriate value.

Consistent with a first embodiment of the present invention, there are provided two mechanisms for lowering the threshold voltage of a PMOS transistor having a gate formed of a metal or a metal compound having an n-type work function. In accordance with the first mechanism, the gate can be treated such that the work function thereof is converted from n-type to mid-gap or p-type. The gate may be treated with a gas such as argon (Ar), nitrogen (N₂), oxygen (O₂), hydrogen (H₂), or a combination thereof, or may be annealed. For example, when treated with a gas combination of argon and nitrogen (for example, ratio of Ar to N₂ being 8:1), a titanium gate formed on hafnium oxide on a silicon substrate exhibits a shift of work function from around 4.3 eV, an n-type work function, to 4.7 eV, a p-type work function, and a tantalum gate formed on hafnium oxide on a silicon substrate exhibits a shift of work function from around 4.3 eV, an n-type work function, to around 4.5 eV, a mid-gap work function.

In one aspect, it is sufficient to treat the gate of the PMOS transistor to achieve an appropriate threshold voltage.

In another aspect, the treatment of the gate of the PMOS transistor is still deficient in achieving an appropriate threshold voltage of the PMOS transistor, and there is further provided a method of band-gap engineering to compensate for such deficiency in accordance with the second mechanism of the first embodiment of the present invention. Particularly, the PMOS transistor implementing the second mechanism may be provided on a structure including an epitaxial layer grown on a semiconductor substrate, where the channel of the PMOS transistor is formed in the epitaxial layer and the epitaxial layer has a mid-gap level that is higher than the mid-gap level of the semiconductor substrate. Thus, the gate, which may have a mid-gap or p-type work function with respect to the semiconductor substrate, has a p-type or p⁺-type work function with respect to the epitaxial layer.

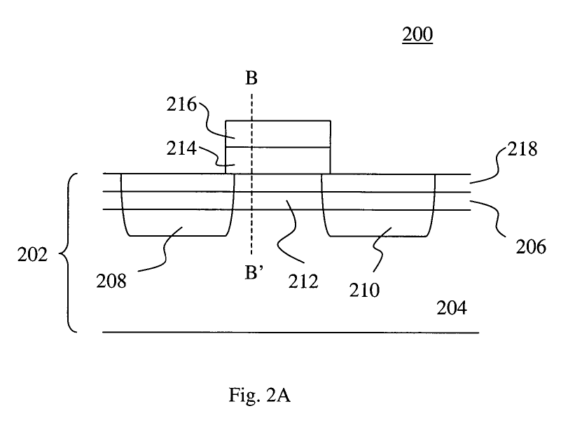

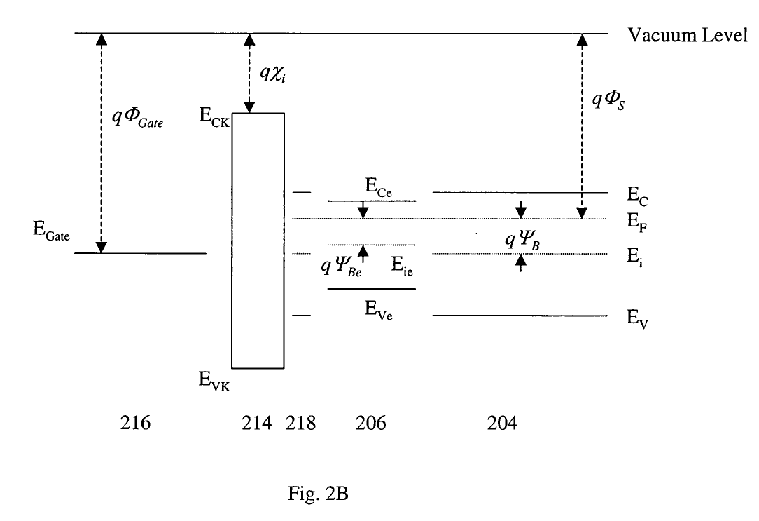

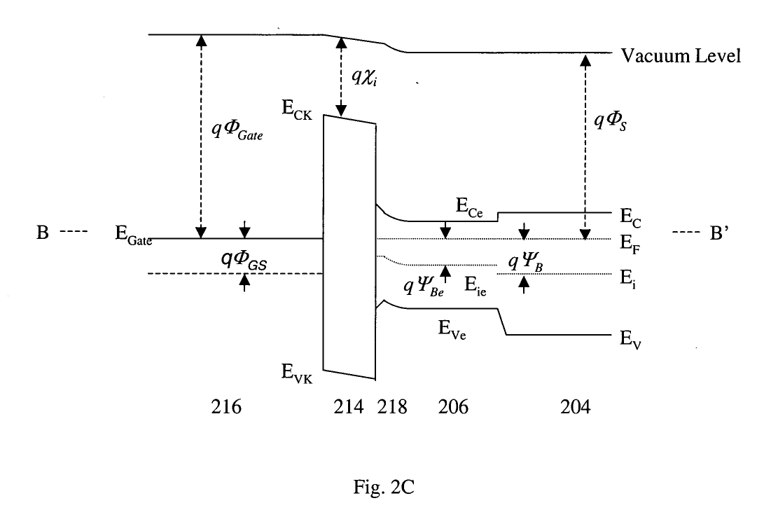

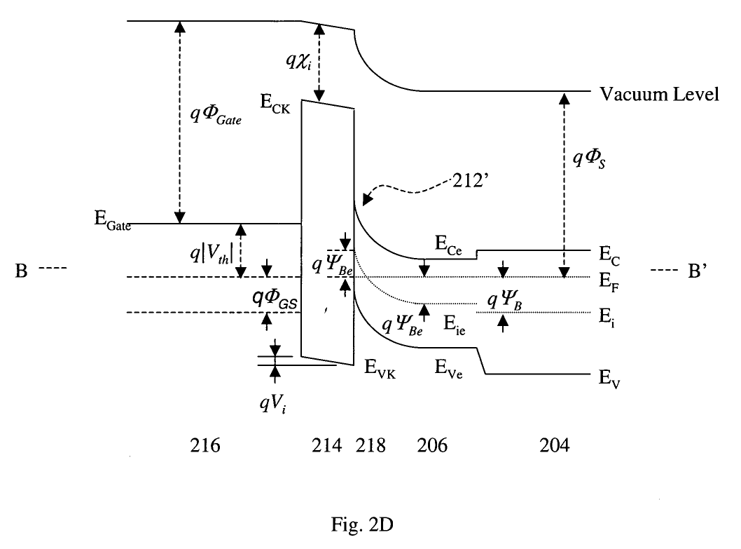

The two mechanisms are explained in further detail below with references to FIGS. 2A-2D.

In FIG. 2A, a PMOS transistor 200 consistent with the first embodiment of the present invention is formed on a substrate 202. Substrate 202 includes a bulk silicon substrate 204 and a first epitaxial layer 206 on bulk silicon substrate 204, both first epitaxial layer 206 and bulk silicon substrate 204 being doped with n-type impurities. A source 208 and a drain 210 are formed in substrate 202. A channel region 212 is defined between source 208 and drain 210. A gate dielectric 214 is formed over channel region 212, and a gate electrode or gate 216 is formed on gate dielectric 214.

Gate dielectric 214 may comprise silicon oxide, silicon nitride, a high-dielectric (high-k) material, or a metal oxide. Gate 216 may comprise a metal or metallic compound having an n-type work function, and is treated with Ar, N₂, O₂, H₂, a combination thereof, or annealing, such that the work function of gate 216 is converted from n-type to mid-gap or p-type. Exemplary metals suitable for gate 216 include Ti, Ta, Al, Zr, Nb, etc. Exemplary metallic compounds suitable for gate 216 include TaN, TaSiₓN_{y}, Ru₁₋ₓTaₓ, etc.

First epitaxial layer 206 comprises strained silicon germanium (SiGe), such as Si₁₋ₓGex, where x<0.7, and may be formed by growing epitaxial SiGe on bulk silicon substrate 204 to a thickness that is no more than a critical thickness of SiGe grown on Si. The critical thickness is defined such that the lattice constant of an epitaxial layer grown on a substrate is approximately equal to the lattice constant of the substrate when the thickness of the epitaxial layer is below the critical thickness, but starts to relax to the normal lattice constant of the material of the epitaxial layer when the thickness of the epitaxial layer is greater than the critical thickness.

In one aspect, substrate 202 further includes a second epitaxial layer 218 on first epitaxial layer 206. Second epitaxial layer 218 comprises a very thin silicon layer such that gate dielectric 214 may later be easily deposited thereon.

FIG. 2B is a flat band diagram illustrating the energy levels of gate 216, gate dielectric 214, second epitaxial layer 218, first epitaxial layer 206, and silicon substrate 204 when they are separated from one another. All of silicon substrate 204, first epitaxial layer 206, and second epitaxial layer 218 are doped with n-type impurities. It is assumed that the Fermi level is the same for silicon substrate 204, first epitaxial layer 206, and second epitaxial layer 218, and is labeled as E_{F} in FIG. 2B. Therefore, the work function is also the same for silicon substrate 204, first epitaxial layer 206, and second epitaxial layer 218, and is labeled as qΦ_{S} in FIG. 2B. It is also assumed that the Fermi level of gate 216 after being treated, E_{Gate}, is approximately at the level of the mid-gap level Eᵢ of silicon substrate 204. Also as shown in FIG. 2B, qΦ_{Gate} is the work function of gate 216; E_{CK} is the conduction band of gate dielectric 214; E_{VK} is the valence band of gate dielectric 214; qχᵢ is the electron affinity of gate dielectric 214; E_{C} is the conduction band of silicon substrate 204; E_{V} is the valence band of silicon substrate 204; Eᵢ is the mid-gap level of silicon substrate 204; qΨ_{B} is the difference between the Fermi level E_{F} and the mid-gap level Eᵢ of silicon substrate 204; E_{Ce} is the conduction band of first epitaxial layer 206; E_{Ve} is the valence band of first epitaxial layer 206; Eᵢₑ is the mid-gap level of first epitaxial layer 206; and qΨ_{Be} is the difference between the Fermi level E_{F} and the mid-gap level Eᵢₑ of first epitaxial layer 206.

As shown in FIG. 2B, the valence band E_{Ve} of first epitaxial layer 206 (Si₁₋ₓGeₓ, x<0.7) is higher than the valence band E_{V} of silicon substrate 204, and the mid-gap level Eᵢₑ of first epitaxial layer 206 is higher than the mid-gap level Eᵢ of silicon substrate 204. Therefore, qΨ_{Be} is smaller than qΨ_{B}, and the Fermi level E_{Gate} of gate 216 is below the mid-gap level Eᵢₑ of first epitaxial layer 206.

FIGS. 2C and 2D illustrate the band diagrams along line B-B′ of FIG. 2A. FIG. 2C is the band diagram when no bias is applied to gate 216 or silicon substrate 204, and FIG. 2D is the band diagram when a negative bias is applied to gate 216 with respect to silicon substrate 204 to create a channel in channel region 212.

As shown in FIG. 2C, at an equilibrium state when no bias is applied to gate 216 or silicon substrate 102, the Fermi levels of gate 216, second epitaxial layer 218, first epitaxial layer 206, and silicon substrate 102 are aligned to one another. Thus, the Fermi level of gate 216 shifts upward with respect to the energy levels of the bulk of substrate 204 by an amount of qΦ_{GS}, where Φ_{GS}=Φ_{Gate}−Φ_{S}.

FIG. 2D illustrates the band diagram when PMOS transistor 200 is turned on by a negative bias applied to gate 216 with respect to silicon substrate 204. Channel 212′ is created in channel region 212 in second epitaxial layer 218 and a surface portion of first epitaxial layer 206 when a strong inversion occurs in the surface portion of first epitaxial layer 206 such that the Fermi level in channel 212′ is below the mid-gap level Eᵢₑ in the surface portion of first epitaxial layer 206 by an amount of qΨ_{Be}. By comparing FIGS. 2C and 2D, there may be derived the threshold voltage Vₜₕ of PMOS transistor 200 as given by Formula (2):
|Vₜₕ|=2Ψ_{Be}−Φ_{GS}+Vi, (2)
if qVᵢ is the amount by which the energy band of gate dielectric 214 bends upward towards gate 216, as shown in FIG. 2D.

As Formula (2) indicates, by treating gate 216, which is formed of a metal or a metallic compound having an n-type work function, the work function of gate 216 is converted from n-type to mid-gap or p-type, as a result of which Φ_{GS} increases. By using a substrate structure including strained SiGe layer 206 on bulk silicon substrate 204, Ψ_{Be} is lowered. An alternative view of the effect of strained SiGe layer 206 is that, as shown in FIG. 2B, because the Fermi level of gate 216 is below the mid-gap level Eᵢₑ of first epitaxial layer 206, the work function of gate 216, which is mid-gap type with respect to substrate 204, may be considered as converted to p-type with respect to first epitaxial layer 206.

In one aspect, PMOS transistor 200 consistent with the first embodiment of the present invention may be formed as follows. First, first epitaxial layer 206 of strained SiGe is grown on bulk Si substrate 204, followed by an epitaxial growth of a thin Si cap as second epitaxial layer 218. Source 208 and drain 210 are formed in thin Si cap 218, strained SiGe 206, and bulk Si substrate 204 by conventional techniques such as implantation and diffusion, where channel region 212 is defined between source 208 and drain 210. Gate dielectric 214 is formed over channel region 212. A metal having n-type work function is then deposited and patterned on gate dielectric 214 to form gate 216. Gate 216 is then treated with gases such as N₂, O₂, H₂, Ar, or a combination thereof, or annealed, whereby the work function thereof is converted from n-type to mid-gap or p-type.

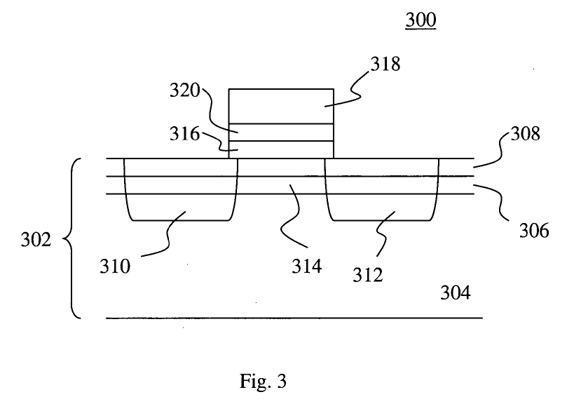

Consistent with a second embodiment of the present invention, in addition to a gate formed of a metal or a metallic compound having an n-type work function, a PMOS transistor may further include gate dielectric formed of a high-dielectric-constant (high-K) material. A PMOS transistor 300 consistent with the second embodiment is shown in FIG. 3.

In FIG. 3, PMOS transistor 300 is formed on a substrate 302 including a Si substrate 304, a strained epitaxial layer 306 of SiGe on Si substrate 304, and a thin Si cap 308 on SiGe layer 306, all of which are doped with n-type impurities. PMOS transistor 300 includes a source 310 and a drain 312 each including a diffusion region in thin Si cap 308, strained SiGe layer 306, and substrate 304. A channel region 314 is defined between source 310 and drain 312. A high-K gate dielectric 316 is provided over channel 314 and a gate electrode or gate 318 is provided over gate dielectric 316.

Gate 318 comprises a material having an n-type work function and may be subjected to treatments such as gas treatment or annealing as discussed above for converting the work function thereof from n-type to mid-gap or p-type.

In one aspect, gate dielectric 316 comprises a hafnium-based high-K material such as hafnium oxide (HfO₂), hafnium silicate (HfSiO), hafnium oxynitride (HfON), or hafnium silicon oxynitride (HfSiON). However, due to the formation of vacant oxygen sites in these hafnium-based materials, the Fermi level at the interface between gate dielectric 316 and a gate electrode is generally pinned at a level above the mid-gap level of silicon. In other words, a gate directly formed on a hafnium-based high-K material could still have an n-type work function, even after being treated with gases like Ar, N₂, O₂, H₂, etc., or annealed.

To improve this situation, PMOS transistor 300 further includes an aluminum oxide (Al₂O₃) cap layer 320 between gate dielectric 316 and gate 318 of PMOS transistor 300. Al₂O₃ deposited on the hafnium-based high-K gate dielectric substantially reduces the Fermi level pinning effect due to vacant oxygen sites formation.

In one aspect, PMOS transistor 300 may be manufactured as follows. First, strained epitaxial layer 306 of SiGe is grown on bulk Si substrate 304, followed by an epitaxial growth of thin Si cap 308. Source 310 and drain 312 are formed in thin Si cap 308, strained SiGe 306, and bulk Si substrate 304 by conventional techniques such as diffusion. A layer of hafnium-based high-K material is then deposited over channel region 314 and patterned to form gate dielectric 316. Al₂O₃ is deposited on gate dielectric 316 to form Al₂O₃ cap layer 320. A metal having n-type work function is deposited on Al₂O₃ cap layer 320 to form gate electrode 318. Gate 318 is then treated with gases such as N₂, O₂, H₂, Ar, or a combination thereof, or annealed, to convert the work function thereof from n-type to mid-gap or p-type.

The PMOS transistor consistent with the first or second embodiment of the present invention may be provided together with an NMOS transistor to form a CMOS device, wherein the same metal may be used as both the gate of the PMOS transistor and the gate of the NMOS transistor, resulting in a lower complexity of a manufacturing process of the CMOS device as compared to conventional CMOS devices with dual-metal-gate structures.

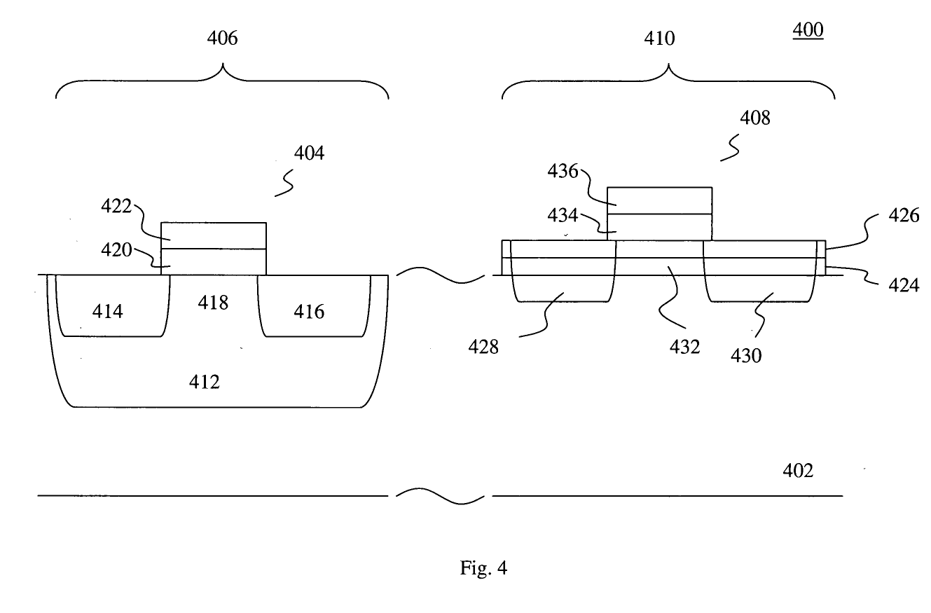

A CMOS device 400 consistent with a third embodiment of the present invention is shown in FIG. 4. CMOS device 400 is formed on an n-type Si substrate 402 and includes an NMOS transistor 404 formed in a first region 406 of Si substrate 402 and a PMOS transistor 408 formed in a second region 410 of Si substrate 402.

In first region 406, there is provided a p-type well 412. NMOS transistor 404 includes a source 414 and a drain 416 each formed by a diffusion region in p-type well 412. A channel region 418 of NMOS transistor 404 is defined between source 414 and drain 416. A layer of gate dielectric 420 is provided over channel region 418 and gate electrode or gate 422 is provided over gate dielectric 420.

In second region 410, an epitaxial layer 424 of strained SiGe is provided on Si substrate 402 and an epitaxial layer 426 of thin Si cap is provided on strained SiGe layer 424. PMOS transistor 408 includes a source 428 and a drain 430 each formed by a diffusion region in Si cap 426, strained SiGe layer 424, and Si substrate 402. A channel region 432 is defined between source 428 and drain 430. A gate dielectric layer 434 is provided over channel region 432 and a gate electrode or gate 436 is provided over gate dielectric 434.

Consistent with the third embodiment, gate 422 of NMOS transistor 404 and gate 436 of PMOS transistor 408 comprise the same metal or metallic compound such that gate 422 and gate 436 may be formed simultaneously by a single step of deposition.

In one aspect, CMOS device 400 may be formed by first forming p-type well 412 in first region 406 of Si substrate 402 and selectively growing epitaxial layers 424 and 426 in second region 410 of Si substrate 402. Conventional processing steps follow to form NMOS transistor 404 and PMOS transistor 408, where a metal or a metallic compound is used as gate material for both NMOS transistor 404 and PMOS transistor 408. Finally, gate 436 of PMOS transistor 408 is treated to convert the work function thereof from n-type to mid-gap or p-type.

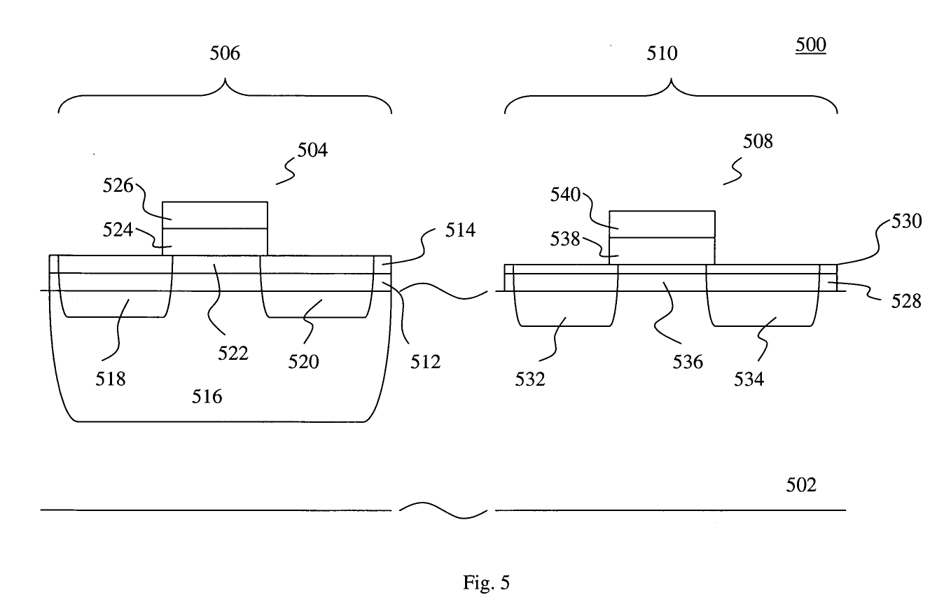

Consistent with a fourth embodiment of the present invention, a CMOS device may include a PMOS transistor and an NMOS transistor, where the PMOS transistor has substantially the same structure as PMOS transistor 408 in FIG. 4, while the NMOS transistor is formed on a structure including a bulk silicon substrate, a strained SiGe layer, and a thick Si cap layer on the strained SiGe layer. FIG. 5 shows a CMOS device 500 consistent with the fourth embodiment.

As shown in FIG. 5, CMOS device 500 is formed on an n-type Si substrate 502 and includes an NMOS transistor 504 formed in a first region 506 of Si substrate 502 and a PMOS transistor 508 formed in a second region 510 of Si substrate 502.

In first region 506, there are selectively grown a first epitaxial layer of relaxed SiGe 512, for example Si₁₋ₓGex, where x<0.7, on Si substrate 502, and a second epitaxial layer of thick strained Si 514 on relaxed SiGe 512. A p-type well 516 is provided in thick Si cap 514, relaxed SiGe layer 512, and Si substrate 502. NMOS transistor 504 includes a source 518 and a drain 520 each formed by a diffusion region in p-type well 516. A channel region 522 of NMOS transistor 504 is defined between source 518 and drain 520. A layer of gate dielectric 524 is provided over channel region 522 and gate electrode or gate 526 is provided over gate dielectric 524.

In second region 510, there are selectively grown an epitaxial layer of strained SiGe layer 528, for example Si₁₋ₓGeₓ, where x<0.7, on Si substrate 502 and a thin Si cap layer 530 on strained SiGe layer 528. PMOS transistor 508 includes a source 532 and a drain 534 each including a diffusion region in thin Si cap 530, strained SiGe layer 528, and Si substrate 502. A channel region 536 is defined between source 532 and drain 534. A gate dielectric layer 538 is provided over channel region 536 and a gate electrode or gate 540 is provided over gate dielectric 538.

Consistent with the fourth embodiment, gate 526 of NMOS transistor 504 and gate 540 of PMOS transistor 508 comprise the same metal or metallic compound such that gate 526 and gate 540 may be formed simultaneously by a single step of deposition.

Also consistent with the fourth embodiment, thick Si cap 514 provided in first region 506 is a strained Si cap such that the electron mobility therein is significantly higher than that in a relaxed or tensile silicon material, and channel 522 is created in a surface region of thick Si cap 514. Accordingly, the speed of NMOS transistor 504 is improved.

In one aspect, CMOS device 500 may be formed as follows. First, epitaxial layers 512, 514, 528, and 530 are selectively grown. P-type well 516 is formed in first region 506. Conventional processing steps follow to form NMOS transistor 504 and PMOS transistor 508, where a metal or a metallic compound is used as gate material for both NMOS transistor 504 and PMOS transistor 508. Finally, gate 540 of PMOS transistor 508 is treated to convert the work function thereof from n-type to mid-gap or p-type.

Although FIGS. 4 and 5 show CMOS devices 400 and 500 as formed on an n-type substrate, one skilled in the art should now understand that they may also be formed on an p-type substrate. For example, NMOS transistor 404 may be formed on an p-type substrate, while PMOS transistor 408 may be formed in an n-type well provided in the p-type substrate.

In the above description, silicon and silicon germanium were used as examples of substrate material and epitaxially grown materials. However, it is to be understood that other semiconductor materials may also be used to compensate for the deficiency of the gate treatment in achieving an appropriate threshold voltage of the PMOS transistor.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device, comprising:
a substrate structure including a semiconductor substrate; and
a PMOS transistor, including
a source and a drain each including a diffusion region in the substrate structure;
a channel region defined between the source and the drain;
a gate dielectric over the channel region; and
a gate electrode over the gate dielectric, wherein the gate electrode is formed of a material having an n-type work function with respect to the semiconductor substrate, the gate electrode treated to convert the n-type work function into a mid-gap type or p-type work function with respect to the semiconductor substrate.

2. The device of claim 1, wherein the gate electrode is treated with argon, nitrogen, hydrogen, or oxygen, or a combination thereof, or an annealing.

3. The device of claim 1, wherein the material having an n-type work function with respect to the semiconductor substrate comprises one of titanium (Ti), tantalum (Ta), aluminum (Al), zirconium (Zr), niobium (Nb), tantalum nitride (TaN), tantalum silicon nitride (TaSiₓN_{y}), and ruthenium tantalum (Ru₁₋ₓTaₓ).

4. The device of claim 1, wherein the semiconductor substrate comprises silicon.

5. The device of claim 1, wherein the substrate structure further includes an epitaxial layer on the semiconductor substrate.

6. The device of claim 5, wherein the semiconductor substrate comprises silicon and the epitaxial layer comprises strained silicon germanium.

7. The device of claim 6, wherein the substrate structure further includes a thin silicon cap layer on the strained silicon germanium.

8. The device of claim 6, wherein the strained silicon germanium comprises strained Si₁₋ₓGeₓ, where x<0.7.

9. The device of claim 1, wherein the gate dielectric layer comprises a layer of hafnium (Hf)-based high-dielectric-constant (high-K) material and a layer of aluminum oxide (Al₂O₃) on the layer of Hf-based high-K material.

10. The device of claim 9, wherein the Hf-based high-K material comprises one of hafnium oxide (HfO₂), hafnium silicate (HfSiO), hafnium oxynitride (HfON), and hafnium silicon oxynitride (HfSiON).

11. A semiconductor device, comprising:
a semiconductor substrate including a first region and a second region;
an NMOS transistor formed in the first region, including
a source and a drain each including a diffusion region,
a channel region defined between the source and the drain,
a gate dielectric over the channel region, and
a gate electrode over the gate dielectric; and
a PMOS transistor formed in the second region, including
a source and a drain each including a diffusion region,
a channel region defined between the source and the drain,
a gate dielectric over the channel region, and
a gate electrode over the gate dielectric,
wherein the gate electrode of the NMOS transistor and the gate electrode of the PMOS transistor are formed of the same material having an n-type work function with respect to the semiconductor substrate, the gate electrode of the PMOS transistor treated to convert the n-type work function thereof to a mid-gap type or p-type work function with respect to the semiconductor substrate.

12. The device of claim 11, wherein the gate electrode of the PMOS transistor is treated with argon, nitrogen, hydrogen, or oxygen, or a combination thereof, or an annealing.

13. The device of claim 11, wherein the material having an n-type work function with respect to the semiconductor substrate comprises one of titanium (Ti), tantalum (Ta), aluminum (Al), zirconium (Zr), niobium (Nb), tantalum nitride (TaN), tantalum silicon nitride (TaSiₓN_{y}), and ruthenium tantalum (Ru₁₋ₓTaₓ).

14. The device of claim 11, further comprising:
a first epitaxial layer on the semiconductor substrate in the second region; and
a second epitaxial layer on the first epitaxial layer in the second region,
wherein the source and the drain of the PMOS transistor each include a diffusion region in the first epitaxial layer, the second epitaxial layer, and the semiconductor substrate, and the channel region of the PMOS transistor includes a portion of the second epitaxial layer and a surface portion of the first epitaxial layer.

15. The device of claim 14, wherein the semiconductor substrate comprises silicon, the first epitaxial layer comprises strained silicon germanium, and the second epitaxial layer comprises a thin silicon cap layer.

16. The device of claim 15, wherein the strained silicon germanium comprises strained Si₁₋ₓGeₓ, where x<0.7.

17. The device of claim 11, wherein the gate dielectric layer of the PMOS transistor comprises a layer of hafnium (Hf)-based high-dielectric-constant (high-K) material and a layer of aluminum oxide (Al₂O₃) on the layer of Hf-based high-K material.

18. The device of claim 17, wherein the Hf-based high-K material comprises one of hafnium oxide (HfO₂), hafnium silicate (HfSiO), hafnium oxynitride (HfON), and hafnium silicon oxynitride (HfSiON).

19. The device of claim 11, further comprising:
a first epitaxial layer on the semiconductor substrate in the first region; and
a second epitaxial layer on the first epitaxial layer in the first region,
wherein the source and the drain of the NMOS transistor each include a diffusion region in the first epitaxial layer, the second epitaxial layer, and the semiconductor substrate, and the channel region of the NMOS transistor includes a surface portion of the second epitaxial layer.

20. The device of claim 19, wherein the semiconductor substrate comprises silicon, the first epitaxial layer comprises relaxed silicon germanium, and the second epitaxial layer comprises a thick silicon cap layer.
